(19) United States
(12) Patent Application Publication
(10) Pub. No.: US 2011/0244184 A1
(43) Pub. Date: Oct. 6, 2011

(54) ALKALINE ETCHING SOLUTION FOR TEXTURING A SILICON WAFER SURFACE

(75) Inventor: Konstantin Holdermann, Hillsboro, OR (US)

(73) Assignee: SOLARWORLD INDUSTRIES AMERICA, INC., Hillsboro, OR (US)

(21) Appl. No.: 12/752,180

(22) Filed: Apr. 1, 2010

(51) Int. Cl. C09K 13/00; C09K 13/02; H01L 21/302; B32B 3/00

(52) U.S. Cl. 428/156; 252/79.1; 252/79.5; 438/753; 257/E21.214

(57) ABSTRACT

An etching solution for texturing a silicon wafer surface is provided. The etching solution may include an aqueous solution of at least one alkaline etching agent and at least one organic compound, wherein the organic compound is a polyalcohol comprising at least four hydroxy groups or a derivative thereof.

### TECHNICAL FIELD

Various embodiments generally relate to an etching solution for texturing a silicon surface.

### BACKGROUND

Alkaline anisotropic etching with potassium hydroxide (KOH) and the additive 2-propanol (IPA) is a widely used step to texture monocrystalline silicon wafers industrially. Texturisation of the wafers is conventionally used to reduce their reflection and thus increase the absorbed light intensity. This may lead to an increased performance of a silicon photovoltaic cell including these wafers.

Using an aqueous solution of an alkali hydroxide and 2-propanol as an etching solution, a texturing time of about 15 to 25 minutes at about 75° C. is required to remove saw damage caused by wafer production and to receive a texture with complete random pyramid coverage.

Alkaline agents like potassium hydroxide and sodium hydroxide are the most commonly used etching reagents in such texturisation processes. Organic etching agents like tetramethylammonium hydroxide and ethylenediamine pyrocatechol require longer treatment times to achieve a similar etching, but they have the effect not to provide metallic cations that can interfere with the electric properties of, e.g. oxidized, silicon substrates.

This is also the reason for the preference of potassium hydroxide over sodium hydroxide, since the sodium ions which remain on the surface after texturing are more likely to interfere with the electric properties of the silicon substrate.

One effect of the currently used processes that use an alkaline agent in combination with 2-propanol (IPA) is that the IPA has to be redosed frequently in a high amount because it easily evaporates during the process.

In addition, IPA is highly flammable, toxic to human beings upon longer exposure, and waste as well as the exhausted vapor require special treatments.

However, known replacements for IPA require higher temperatures or loner etching times to achieve a similar etching result and are relatively expensive. Higher reaction temperatures mean that the process consumes more energy and instead of plastic equipment the more expensive stainless steel equipment has to be used for the process.

There is thus need in the art for an etching solution that may partially or completely overcome the above-mentioned effects of the conventional techniques while retaining some or all of the advantages of the currently used etching solutions.

### SUMMARY

An etching solution for texturing a silicon wafer surface is provided. The etching solution may include an aqueous solution of at least one alkaline etching agent and at least one organic compound, wherein the organic compound is a polyalcohol comprising at least four hydroxy groups or a derivative thereof.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments are described with reference to the following drawings, in which:

FIG. 1 shows a scanning electron microscope (SEM) image of a silicon wafer surface as cut after texture etching for 15 minutes with an aqueous solution of 9 wt.-% raffinose and 3 wt.-% NaOH at 75° C.

FIG. 2 shows an SEM image of a saw damage etched silicon wafer surface after texture etching for 15 minutes with an aqueous solution of 9 wt.-% raffinose and 3 wt.-% NaOH at 75° C.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

In the context of the various embodiments, the following terms have the meaning indicated below unless explicitly indicated otherwise.

The term “polyalcohol” as used herein refers to an organic compound that includes more than one hydroxy group. The basic structure of the polyalcohol may be an alkane, alkene, alkine, cycloalkane, cycloalkene, aryl or heteroaryl which may be substituted with other functional groups, such as carbonyl, primary, secondary and tertiary amine, sulfonyl, phosphonyl, carboxy, and the like.

The term “hydroxy group” or “hydroxyl group” as interchangeably used herein refers to an —OH group.

The term “carbohydrate” as used herein refers to sugars and may include monosaccharides, disaccharides, trisaccharides, oligosaccharides, and polysaccharides. Disaccarides, trisaccharides, oligosaccharides and polysaccharides comprise two, three or more monosaccharide units that are linked by a covalent (glycosidic) bond. Exemplary monosaccharides include but are not limited to erythrose, threose, erythrulose, ribose, arabinose, xylose, lyxose, ribulose, xylulose, allose, altrose, glucose, mannose, gulose, idose, galactose, talose, psicose, fructose, sorbose and tagatose.

The term “non-reducing sugar” as used herein refers to a disaccharide, trisaccharide, oligosaccharide or polysaccharide that has no reducing activity, i.e. that cannot act as a reducing agent, for example in the Maillard reaction, Benedict's reaction or Fehling's reaction. Non-reducing sugars are di-, tri, oligo- or polysaccharides wherein the anomeric carbon atoms of all monosaccharide units are blocked by a glycosidic bond and include, but are not limited to sucrose, trehalose and raffinose.

The expression “reducing sugar” as used herein relates to any sugar that acts as a reducing agent, for example in the Maillard reaction, Benedict's reaction or Fehling's reaction. Reducing sugars are those sugars in which the anomeric carbon atom of one or more monosaccharide units (the carbon which is linked to two oxygen atoms) is in the free form, i.e. does not form part of a glycosidic bond. This allows the sugar to convert into the linear aldehyde or ketone (i.e. the chain-form), where the aldehyde group can be oxidized to a carboxyl group via a redox reaction.

The term “sugar alcohol” as used herein relates to polyalcohols that are derived from carbohydrates by reduction of the aldehyde or keto group. Sugar alcohols include, but are not limited to sorbitol (glucitol), mannitol, xylitol, maltitol, lactitol, erythritol, arabitol, isomalt, threitol, ribitol, dulcitol, iditol, and polyglycitol.

The term “sugar acid” as used herein relates to a hydroxy carboxylic acid that is derived from a sugar by oxidizing the aldehyde group. Exemplary sugar acids may include aldonic and uronic acids, such as xylonic acid, gluconic acid, ascorbic acid, glucuronic acid, galacturonic acid, iduronic acid, tataric acid, mucic acid and saccharic acid.

The expression “derivative”, as used herein in connection with the polyalcohols of various embodiments, relates to a compound that differs from the corresponding polyalcohol in that at least one of the hydroxy groups is replaced by another group, such as an oxo (═O) group, and thus includes, but is not limited to aldehydes, ketones, carboxylic acids, amides, and the like. Exemplary derivatives are aldehydes, ketones and carboxylic acids that include one or more hydroxy groups.

The term “about” as used herein in combination with a numeric value means that the given value can vary in a range of about ±20%, preferably about ±10% relative to the given numeric value.

Various embodiments are based on the inventor's finding that in an alkaline etching solution for texture etching a silicon wafer surface, the 2-propanol additive can be replaced by a carbohydrate or derivative thereof without impairing the etching efficacy of the solution. These solutions may have the effect that the utilized carbohydrates or derivatives thereof have a much higher boiling point and thus do not evaporate during the etching process. In addition, they are inexpensive, non-toxic and not highly flammable, but still provide for fast and efficient etching at a temperature between 70 and 80° C. so that plastic equipment can be used for the etching process instead of the more expensive stainless steel equipment necessary if higher temperatures are employed. Finally, these types of additives are safe under environmental aspects.

Various embodiments thus feature an etching solution for texturing a silicon surface, for example a silicon wafer surface, including an aqueous solution of at least one alkaline etching agent and at least one organic compound, wherein the organic compound is a polyalcohol comprising at least four hydroxy groups or a derivative thereof.

The polyalcohol or polyalcohol derivative may be selected from the group consisting of linear, branched or cyclic C₄-C₁₈ polyalcohols including at least four hydroxy groups or derivatives thereof.

In one embodiment, the polyalcohol is selected from the group consisting of sorbitol (glucitol), mannitol, xylitol, maltitol, lactitol, erythritol, arabitol, isomalt, threitol, ribitol, dulcitol, iditol, polyglycitol, inositol, volemitol and mixtures thereof.

In another embodiment, the organic compound is a polyalcohol derivative. The polyalcohol derivative may be an oxidized derivative of a polyalcohol, wherein at least one hydroxy group is replaced by an oxo (═O) group, including but not limited to ketones, aldehydes and carboxylic acids. The derivative may itself include two or more, e.g. three or more, e.g. four or more hydroxy groups.

In various embodiments, the polyalcohol derivative is a carbohydrate, including, but not limited to a monosaccharide, disaccharide, trisaccharide, oligosaccharide, polysaccharide or mixtures thereof. The disaccharide, trisaccharide, oligosaccharide and polysaccharide may consist of one type of monomers (monosaccharide) or two or more different types of monomers (monosaccharides). The polysaccharide may be a homo- or heteropolysaccharide. The polysaccharide may contain non-carbohydrate units.

In various embodiments, the carbohydrate may be a non-reducing sugar. This non-reducing sugar may be selected from the group consisting of sucrose, trehalose, raffinose and mixtures thereof.

In various embodiments, the carbohydrate is not a reducing sugar, such as monosaccharides like glucose, fructose, and lactose.

In another embodiment of the invention, the polyalcohol derivative is a sugar acid or salt thereof. The sugar acid may be selected from the group consisting of xylonic acid, gluconic acid, ascorbic acid, glucuronic acid, galacturonic acid, iduronic acid, tataric acid, mucic acid, saccharic acid and mixtures and salts thereof.

Also contemplated by various embodiments are etching solutions that include more than one of the above detailed organic compounds, for example two or more different polyalcohols or polyalcohol derivatives.

In one embodiment of the invention the etching solution includes at least two organic compounds, wherein the first organic compound is a polyalcohol comprising at least four hydroxy groups and the second organic compound is a polyalcohol derivative. The polyalcohol derivative may be as defined above and can, for example, be a carbohydrate.

In one embodiment of the invention, the etching solution includes at least two organic compounds, wherein the organic compounds are both polyalcohol derivatives with the first polyalcohol derivative being a sugar acid and the second polyalcohol derivative being a carbohydrate.

In various embodiments, the etching solution contains about 0.5 to about 20% by weight, e.g. about 0.5 to about 10% by weight, e.g. about 1 to about 10% by weight, e.g. about 1.5 to about 5% by weight of the organic compound.

The alkaline etching agent may be selected from the group consisting of sodium hydroxide, potassium hydroxide, potassium carbonate, sodium carbonate, calcium hydroxide, tetramethylammonium hydroxide, ethylenediamine pyrocatechol and mixtures thereof. In a preferred embodiment, the alkaline etching agent is sodium hydroxide or potassium hydroxide, preferably potassium hydroxide.

In various embodiments, the etching solution contains about 0.25 to about 15% by weight, preferably about 0.5 to about 7% by weight of the alkaline etching agent.

In various embodiments, the etching solution may further include at least one surfactant. The surfactant may be selected from the group comprising but not limited to sodium lauryl sulfate, polyethylene glycol, polyethylene glycol octylphenyl ether and mixtures thereof. The surfactant may be present in a concentration of about 1 to about 20% by weight, e.g. of about 2 to about 10% by weight of the etching solution.

The etching solutions of various embodiments may further include one or more auxiliaries which are known to those skilled in the art. Exemplary auxiliaries may include but are not limited to viscosity-controlling agents and the like. Further auxiliaries that may be used to control the size of the pyramidal shapes generated by texture etching are gaseous agents, such as air, oxygen, ozone, and nitrogen, which may be solved in the etching solution.

In various embodiments, the etching solution may be prepared with degassed water to control the size of the pyramidal shapes on the silicon wafer surface.

Exemplary etching solutions of various embodiments may include but are not limited to aqueous solutions of about 0.25 to about 5 wt.-%, preferably about 0.5 to about 3 wt.-% potassium hydroxide or sodium hydroxide and about 2 to about 10, e.g. about 2.5 to about 9 wt.-% of a non-reducing sugar, such as sucrose, trehalose or raffinose, a sugar alcohol, such as xylitol, mannitol or sorbitol, or inositol.

Various embodiments relate to a process for etching of a silicon wafer, including contacting the silicon wafer with an etching solution according to various embodiments. This etching may be texture etching and/or damage etching.

In various embodiments of this process, the etching solution has a temperature of about 70 to about 95° C., e.g. of about 72 to about 90° C., e.g. of about 72 to about 80° C., e.g. of about 72 to about 85° C.

The contacting may include spraying or dripping the etching solution onto the silicon wafer or immersing the wafer in the etching solution.

The contacting time of the silicon wafer with the etching solution may be in the range of about 10 to about 25 minutes, e.g. from about 10 to about 15 minutes.

In various embodiments of this process, the etching solution is stirred, circulated or agitated, for example by a stiffer, ultrasonic, shaker or pump. This may facilitate the diffusion of the etching agents to the wafer surface and the diffusion of reaction products away from the wafer surface and the maintenance of a constant reaction temperature.

Various embodiments are directed to a silicon wafer obtained according to the process as described above.

Also encompassed by various embodiments are photovoltaic cells including the silicon wafer according to various embodiments.

Various embodiments are directed to the use of the etching solution of the invention for texturing the surface of a silicon wafer.

Using the invented etching solutions for the texture etching of silicon wafers, either as cut or saw damage etched or surface-polished prior to texture etching, a high coverage of uniform pyramidal structures can be formed on the surface of the silicon wafer. The resulting wafers may have a high light absorbance.

In one embodiment of the above processes and uses, the silicon wafer used in the process may be a monocrystalline silicon wafer.

The silicon wafer may be a saw damaged silicon wafer, a silicon wafer that has already been subjected to an etching step to remove saw damage (“damage etched silicon wafer”) or a polished silicon wafer.

### EXAMPLES

The following examples serve as a means to illustrate the various embodiments and should not be construed as limiting the scope of protection of the various embodiments.

### Example 1

Monocrystalline silicon wafers were laser cut into 30 mm×30 mm squares. The etching solution was prepared in 1 L beakers on a temperature controlled hot plate stirrer and heated to 75 or 80° C. For texture etching, 4 wafer squares—two as cut and two saw damage etched prior to texture etching—were fixed to a carrier and completely immersed in the etching solution contained in the beaker. The following etching solutions were used:

Solution A: 2.5 wt.-% sucrose, 3 wt.-% NaOH;

Solution B: 3 wt.-% trehalose, 3 wt.-% NaOH;

Solution C: 9 wt.-% raffinose, 3 wt.-% NaOH;

The results obtained with each of these solutions at different etch times are listed in Table 1 below.

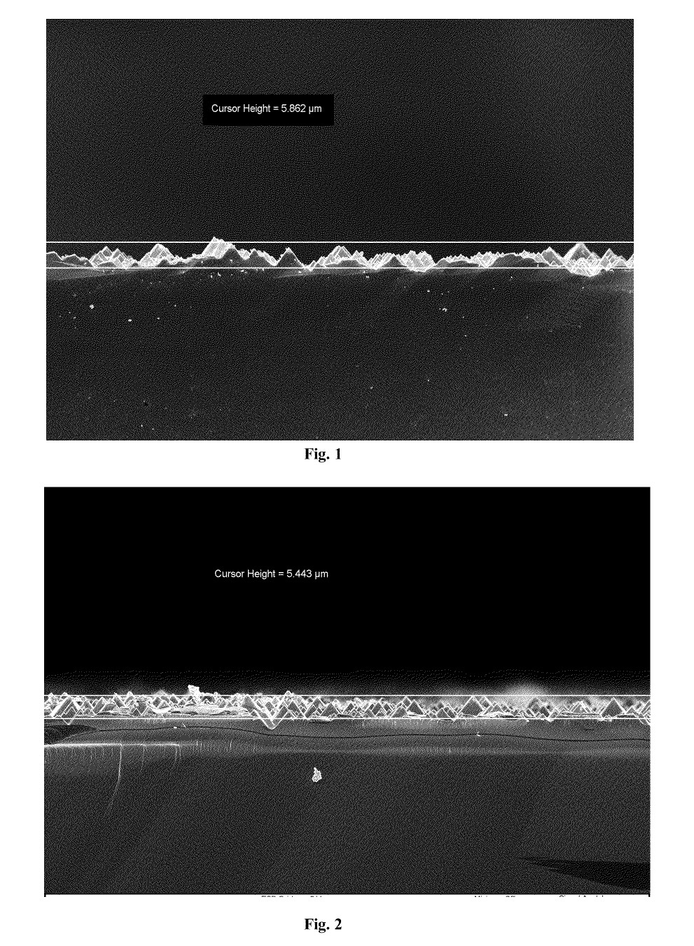

The pyramidal shapes generated on the wafer surface by the texture etching solution and process of the invention using Solution C is shown, by way of example, in the SEM images of the wafer surface in FIG. 1 (wafer as cut) and 2 (saw damage etched wafer). Similar pyramidal shapes were generated using Solutions A and B.

TABLE 1

| | | | Total removal (μm) | |
|---|---|---|---|---|
| | Etch time | Temperature | Wafers damage | Wafers |
| Solution | (min) | (° C.) | etched | as cut |
| A | 15 | 75 | 7.0 | 16.9 |
| A | 20 | 75 | 6.4 | 15.9 |
| A | 30 | 75 | 6.8 | 18.6 |
| B | 15 | 75 | 9.4 | 15.4 |
| B | 20 | 75 | 11.4 | 17.7 |
| C | 15 | 75 | 11.6 | 16.2 |
| C | 20 | 75 | 13.8 | 17.8 |

### Example 2

Monocrystalline silicon wafers were laser cut into 30 mm×30 mm squares. The etching solution was prepared in 1 L beakers on a temperature controlled hot plate stirrer and heated to 72 or 80° C. For texture etching, 4 wafer squares—two as cut and two saw damage etched prior to texture etching—were fixed to a carrier and completely immersed in the etching solution contained in the beaker. The following etching solution was used: 3.0 wt.-% Sorbitol, 2.4 wt.-% NaOH.

The results obtained with this solution at different etch times and temperatures are listed in Table 2 below.

TABLE 2

| Etch time | Temperature | Total removal (μm) | |
|---|---|---|---|
| (min) | (° C.) | Wafers damage etched | Wafers as cut |
| 10 | 77 | 7.3 | 12.2 |
| 15 | 72 | 8.5 | 13.4 |

Various embodiments generally relate to an etching solution for texturing a silicon surface, the etching solution including an alkaline etching agent and at least one organic compound as well as the use thereof for texturing a silicon surface. Also encompassed by various embodiments are processes for the etching of a silicon wafer using the etching solutions according to various embodiments, the thus obtained silicon wafers and photovoltaic cells including such wafers.

Various embodiments may meet the above need and may provide an etching solution for texturing a silicon wafer surface including an additive that is less prone to evaporation during the etching process, inexpensive and relatively non-toxic, but still provides for rapid etching at temperatures below 80° C.

Various embodiments are directed to an etching solution for texturing a silicon wafer surface including an aqueous solution of at least one alkaline etching agent and at least one organic compound, wherein the organic compound is a polyalcohol comprising at least four hydroxy groups or a derivative thereof.

Various embodiments relate to a process for etching of a silicon wafer, including contacting the silicon wafer with an etching solution according to various embodiments. This etching may be texture etching only or texture etching that includes damage etching.

Various embodiments may be directed to a silicon wafer obtained according to the process of various embodiments or a photovoltaic cell including such a wafer.

Various embodiments may be directed to the use of the etching solution of various embodiments for texturing the surface of a silicon wafer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An etching solution for at least one of texturing a silicon wafer surface, the etching solution comprising:
an aqueous solution of at least one alkaline etching agent and at least one organic compound,
wherein the organic compound is a polyalcohol comprising at least four hydroxy groups or a derivative thereof.

2. The etching solution according to claim 1,
wherein the polyalcohol or polyalcohol derivative is selected from the group consisting of linear, branched or cyclic C₄-C₁₈ polyalcohols comprising at least four hydroxy groups or derivatives thereof.

3. The etching solution according to claim 2,
wherein the polyalcohol is selected from the group consisting of sorbitol, mannitol, inositol, xylitol, maltitol, lactitol, erythritol, arabitol, isomalt, threitol, ribitol, dulcitol, iditol, polyglycitol, inositol, volemitol and mixtures thereof.

4. The etching solution according to claim 1,
wherein the polyalcohol derivative is a carbohydrate.

5. The etching solution according to claim 4,
wherein the carbohydrate is selected from the group consisting of monosaccharides, disaccharides, trisaccharides, oligosaccharides, polysaccharides and mixtures thereof.

6. The etching solution according to claim 5,
wherein the carbohydrate is a non-reducing sugar.

7. The etching solution according to claim 6,
wherein the non-reducing sugar is selected from the group consisting of sucrose, trehalose, raffinose and mixtures thereof.

8. The etching solution according to claim 1,
wherein the polyalcohol derivative is a sugar acid or salt thereof.

9. The etching solution according to claim 8,
wherein the sugar acid is selected from the group consisting of xylonic acid, gluconic acid, ascorbic acid, glucuronic acid, galacturonic acid, iduronic acid, tataric acid, mucic acid, saccharic acid and mixtures and salts thereof.

10. The etching solution according to claim 1,
wherein the etching solution contains about 0.5% to about 10% by weight of the organic compound.

11. The etching solution according to claim 1,
wherein the alkaline etching agent is selected from the group consisting of sodium hydroxide, potassium hydroxide, potassium carbonate, sodium carbonate, calcium hydroxide, tetramethylammonium hydroxide, ethylenediamine pyrocatechol and mixtures thereof.

12. The etching solution according to claim 1,
wherein the etching solution contains about 0.5 to about 7% by weight of the alkaline etching agent.

13. The etching solution according to claim 1,
wherein the solution further comprises at least one surfactant.

14. The etching solution according to claim 13,
wherein the surfactant is selected from the group consisting of sodium lauryl sulfate, polyethylene glycol, polyethylene glycol octylphenyl ether and mixtures thereof.

15. The etching solution according to claim 13,
wherein the etching solution contains about 1 to about 20% by weight of the surfactant.

16. An etching solution according to claim 1,
wherein the etching solution comprises at least two organic compounds, wherein the first organic compound is a polyalcohol comprising at least four hydroxy groups and the second organic compound is a polyalcohol derivative, wherein said polyalcohol derivative is a carbohydrate.

17. An etching solution according to claim 1,
wherein the etching solution comprises at least two organic compounds, wherein the organic compounds are polyalcohol derivatives, wherein the first polyalcohol derivative is a sugar acid and the second polyalcohol derivative is a carbohydrate.

18. An etching process for texturing a silicon wafer, the process comprising:
contacting the silicon wafer with an etching solution, the etching solution comprising:
an aqueous solution of at least one alkaline etching agent and at least one organic compound,
wherein the organic compound is a polyalcohol comprising at least four hydroxy groups or a derivative thereof.

19. The process according to claim 18,
wherein the contacting comprises immersing the silicon wafer in the etching solution.

20. The process according to claim 18,
wherein the etching solution has a temperature of about 70 to about 85° C.

21. The process according to claim 18,
wherein the silicon wafer is contacted with the etching solution for about 10 to about 25 minutes.

22. The process according to claim 18,
wherein the silicon wafer is a monocrystalline silicon wafer.

23. The process according to claim 18,
wherein the silicon wafer is a wafer selected from a group consisting of a saw damaged silicon wafer; a damage etched silicon wafer; and a polished silicon wafer.

24. Silicon wafer obtained according to a process for the etching of a silicon wafer, the process comprising:
contacting the silicon wafer with an etching solution, the etching solution comprising:
an aqueous solution of at least one alkaline etching agent and at least one organic compound,
wherein the organic compound is a polyalcohol comprising at least four hydroxy groups or a derivative thereof.
